(19) United States
(12) Patent Application Publication
(10) Pub. No.: US 2026/0127768 A1
(43) Pub. Date: May 7, 2026

(54) BLOCK-BASED DATA COMPRESSION WITH SHARED EXPONENTS

(71) Applicant: Microsoft Technology Licensing, LLC, Redmond, WA (US)

(72) Inventors: Christian Markus MAEKELAE, Monroe, WA (US); Casey Lee MILLER, Fort Collins, CO (US); Michael BLEYER, Seattle, WA (US)

(73) Assignee: Microsoft Technology Licensing, LLC, Redmond, WA (US)

(21) Appl. No.: 18/936,666

(22) Filed: Nov. 4, 2024

(51) Int. Cl. G06T 9/00; G06T 3/40

(52) U.S. Cl. CPC G06T 9/00; G06T 3/40

(57) ABSTRACT

A method for data compression includes dividing a dataset of data elements into a plurality of blocks, such that each block includes a subset of data elements, and each block has a predetermined size. Compressed floating-point representations are calculated for the subset of data elements of each block. The compressed floating-point representations are calculated by, for each data element in a block, selecting a selected exponent from a set of two or more exponents, wherein two or more data elements of the block share the selected exponent; and for each data element in the block, calculating a mantissa value, such that the mantissa value and the selected exponent for the data element together comprise a compressed floating-point representation of the data element. The compressed floating-point representations for the subset of data elements of each block are stored in a compressed representation of the dataset.

### BACKGROUND

Data compression techniques are widely used in various fields, such as digital communication, multimedia processing, and data storage, to reduce the amount of data required to represent information. One class of data compression methods, referred to as block-based data compression, involves dividing data into different blocks, and applying compression algorithms to each block individually.

### SUMMARY

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter. Furthermore, the claimed subject matter is not limited to implementations that solve any or all disadvantages noted in any part of this disclosure.

A method for data compression includes dividing a dataset of data elements into a plurality of blocks, such that each block includes a subset of data elements, and each block has a predetermined size. Compressed floating-point representations are calculated for the subset of data elements of each block. The compressed floating-point representations are calculated by, for each data element in a block, selecting a selected exponent from a set of two or more exponents, wherein two or more data elements of the block share the selected exponent; and for each data element in the block, calculating a mantissa value, such that the mantissa value and the selected exponent for the data element together comprise a compressed floating-point representation of the data element. The compressed floating-point representations for the subset of data elements of each block are stored in a compressed representation of the dataset.

### BRIEF DESCRIPTION OF THE DRAWINGS

FIGS. 1A-1C schematically depict an example dataset including a plurality of data elements divided into blocks.

FIG. 2 illustrates an example method for data compression.

FIG. 3 schematically illustrates compression of a dataset into a compressed dataset representation that includes a plurality of compressed floating-point representations of data elements.

FIGS. 4A-4C schematically illustrate calculating and storing compressed floating-point representations for data elements of a dataset.

FIG. 5 schematically shows an example compressed dataset representation including a block-level shared exponent set.

FIG. 6 schematically shows an example compressed dataset representation including a dataset-level shared exponent set.

FIG. 7 illustrates an example method for data decompression.

FIG. 8 schematically shows an example computing system.

### DETAILED DESCRIPTION

Memory bandwidth often causes a bottleneck in computer data processing, particularly when large datasets are processed using graphics processing units (GPUs). This may be exacerbated when the data is represented in floating point format, which commonly uses 32 bits of data per data element. Retrieving such a relatively high number of bits per data value can saturate the available memory bandwidth, thereby slowing the overall data processing operation. While memory bandwidth can be conserved by reducing the number of bits used to store each data element, this can negatively reduce both the precision with which the data is represented (e.g., when fewer bits are used for storing the mantissa), and/or the dynamic range (e.g., when fewer bits are used for storing the exponent).

Accordingly, the present disclosure is directed to techniques for data compression that can beneficially reduce the number of bits used to store each data element, while still preserving suitable precision and dynamic range. For instance, the present disclosure primarily focuses on cases where the dataset is a digital image, and the data elements are pixel values. However, this is non-limiting. As other examples, datasets may include digital video (e.g., a sequence of video frames), digital audio (e.g., comprising a plurality of audio samples as data elements), text data (e.g., comprising a plurality of tokens), matrices for network operations (e.g., comprising a plurality of parameters), and/or any other suitable computer data. While the present disclosure primarily focuses on datasets in which the initial, uncompressed data elements take the form of floating-point values, which are then compressed into compressed floating-point representations of the data elements, this is non-limiting. Rather, the compression techniques discussed herein may be applied to any suitable input data, expressed in any suitable form. For instance, the dataset may include integer values, which are converted into floating-point values and then compressed using the compression techniques described herein.

Specifically, the present disclosure describes a block-based compression technique, in which data elements of a dataset are divided into a plurality of blocks, each having the same predetermined size. As a result of the compression process, compressed floating-point representations are calculated for each of the data elements, where each compressed floating-point representation has an exponent and a mantissa. Notably, according to the present disclosure, two or more compressed floating-point representations in the same block share the same exponent. In other words, during compression, exponents are selected from a shared exponent set for each data element, such that at least two data elements in a given block share the same selected exponent. The system then calculates different mantissa values for each data element based at least in part on the selected exponents. In this manner, a block of data elements can be represented as a set of unique mantissa values, along with corresponding indicator bits specifying which exponents of the shared exponent set were selected for each data element. In some examples, the mantissa values may be transformed using a mantissa transformation function to improve precision, as will be described in more detail below. Furthermore, in some cases, use of shared exponents can additionally enable space-efficient encoding of negative floating-values, as will be described in more detail below.

The techniques described herein beneficially result in a reduction in the number of bits used to store each data element. The initial dataset of data elements is represented using a first quantity of bits, and the compressed representation of the dataset is represented using a second, smaller quantity of bits, which conserves data storage space and memory bandwidth of the computing system. For instance, rather than separately encoding different unique exponents for each value, the compressed floating-point representations may instead be associated with index indicators specifying which exponent of the shared exponent set is used for that data element, where the index indicators use less storage space. Furthermore, the block-based nature of the data compression process beneficially enables fast random access to the compressed data. In other words, a given data element can be retrieved without having to decode a significant portion of the entire compressed dataset, which would be necessary in some other compression techniques. As a result, the techniques described herein beneficially result in improvements to data processing speed (e.g., enabling data processing operations to be performed faster without memory bandwidth causing a bottleneck), and improvements to data storage efficiency (e.g., using fewer bits to store the same information) while preserving suitable data precision and dynamic range.

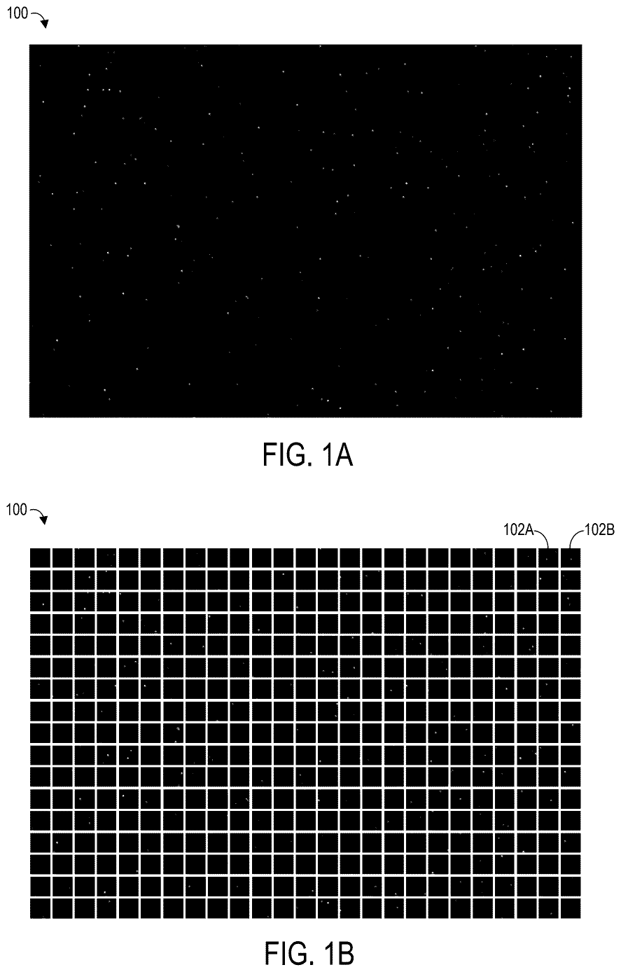

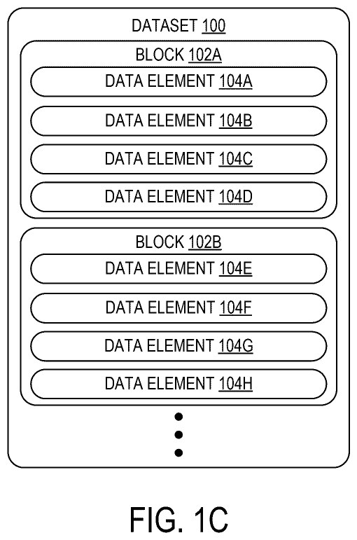

FIG. 1A shows a representation of an example dataset 100. In this example, the dataset takes the form of a digital image, and the data elements of the dataset are pixel values of the digital image. More particularly, in this example, the dataset is a dark frame calibration image used in digital imaging. A dark frame calibration image refers to an image captured by a camera or imaging sensor with no incoming light, in order to measure and correct for noise that is inherent to the camera sensor itself, such as thermal noise and dark current.

The techniques discussed herein may be particularly advantageous when used to compress dark frame calibration images, as such images often include both very small and very large values—e.g., the values have a relatively high dynamic range. Furthermore, it is generally important to reproduce the values with relatively high precision. Using an integer format to encode values of the dark frame calibration image can result in a lack of suitable precision and/or suitable dynamic range. By contrast, as will be described in more detail below, the techniques described herein enable pixel values of a dark frame calibration image to be compressed using compressed floating-point representations, having improved precision and dynamic range as compared to integer representations.

It will be understood that the dataset of FIG. 1A is a non-limiting example. The techniques discussed herein may be applied to other types of digital images besides dark frame calibration images, and other types of datasets besides digital images. For instance, in this case, the dataset is a two-dimensional dataset (e.g., a two-dimensional grid of image pixels), although this is non-limiting. In other scenarios, the compression techniques described herein may be applied to one-dimensional, three-dimensional, or n-dimensional datasets, including any arbitrary computer data. Furthermore, it will be understood that data elements generally take the form of individual data values, or other suitable atomic units of a larger dataset. For instance, the present disclosure primarily focuses on scenarios where the data elements are pixel values, although this is non-limiting.

The present disclosure primarily focuses on cases where the dataset is being processed by a GPU (e.g., as part of an image processing pipeline), although this is non-limiting. For instance, the techniques described herein may be implemented in cases where data is being transferred between different separate compute nodes, or being transferred between different intermediate layers in a deep neural network (DNN). In general, the techniques described herein may be applied to any suitable computer data, in any suitable data processing context.

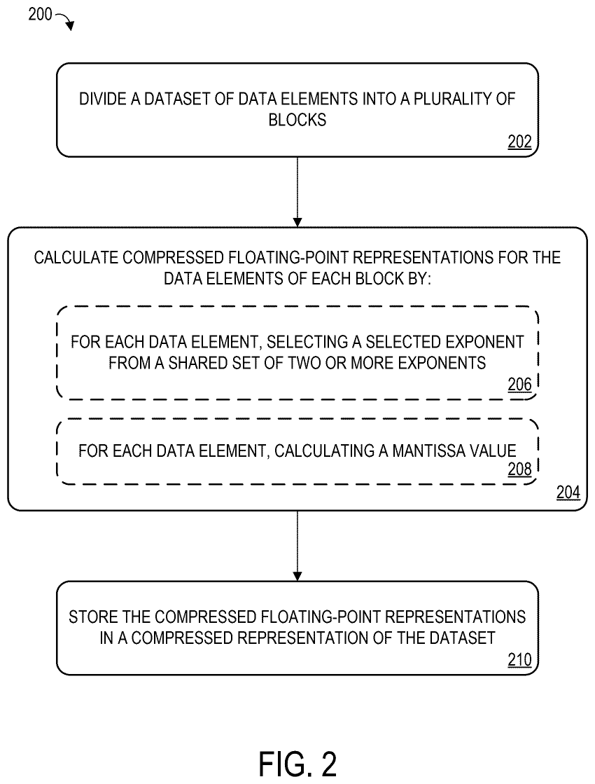

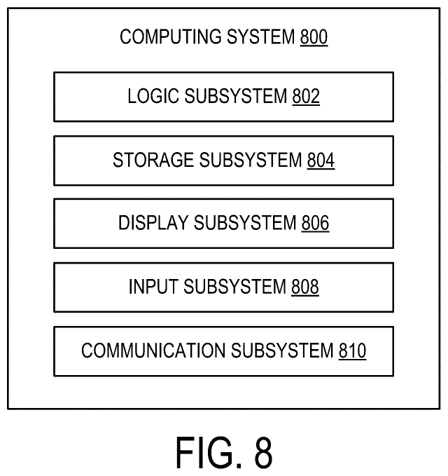

With respect to FIG. 1A, the dataset 100 includes a plurality of data elements (e.g., pixel values) that are compressed into compressed floating-point representations. To that end, FIG. 2 illustrates an example method 200 for data compression. Steps of method 200 may be initiated, terminated, and/or repeated at any suitable time and in response to any suitable condition. Steps of method 200 may be implemented by any suitable computing system of one or more computing devices. Any computing device implementing steps of method 200 may have any suitable capabilities, hardware configuration, and form factor. As one example, method 200 may be implemented by computing system 800 described below with respect to FIG. 8.

### Blocks

At 202, method 200 includes dividing a dataset into a plurality of blocks, such that each block includes a subset of the data elements of the dataset, and each block has the same predetermined size. For instance, in scenarios where the dataset is a digital image, then each block may include the same number of pixels. As non-limiting examples, the blocks may be 2×2 blocks (e.g., four pixels total) or 4×4 blocks (e.g., 16 pixels total). Each block is stored in computer storage using the same number of bits. For instance, in cases where the blocks are 2×2 or 4×4 and include pixel values of a digital image, then each block may be stored using 32 or 128 bits per block, as non-limiting examples. However, it will be understood that the blocks may have any suitable size, depending on the type of data in the dataset. In some examples, non-square block sizes may be used—e.g., each block may have a size of 32×4.

Division of a dataset into a plurality of blocks is schematically illustrated with respect to FIG. 1B, again showing dataset 100 of FIG. 1A. In this example, the dataset has been divided into a plurality of blocks, indicated by the white lines dividing the image into different squares. Two of the plurality of blocks are labelled as blocks 102A and 102B. As shown, each block is the same size, and thus includes the same number of data elements—e.g., pixels of the digital image. Many of the blocks include a mix of relatively white and relatively dark pixels, meaning the underlying data elements within each block have a relatively high dynamic range.

It will be understood that the representation shown in FIG. 1B is deliberately simplified and presented only for the sake of explanation. For instance, the dataset may be divided into blocks having a smaller relative size than those shown in FIG. 1B. Additionally, it will be understood that blocks will typically be divisions that are not graphically represented for viewing by a user, as is shown in FIG. 1B, but rather are internal divisions generated only for the sake of data compression.

FIG. 1C shows an alternative, schematic representation of dataset 100. As discussed above, the dataset is divided into a plurality of blocks, two of which are labelled as blocks 102A and 102B. It will be understood that a dataset may be divided into any suitable number of two or more blocks, and may include hundreds, thousands, or millions of blocks, depending on the nature of the dataset and the size of each block. Furthermore, each block includes the same number of data elements. In this example, each block includes four data elements. For instance, block 102A includes data elements 104A-104D, and block 102B includes data elements 104E-104H. However, in other examples, each block may include a different number of data elements.

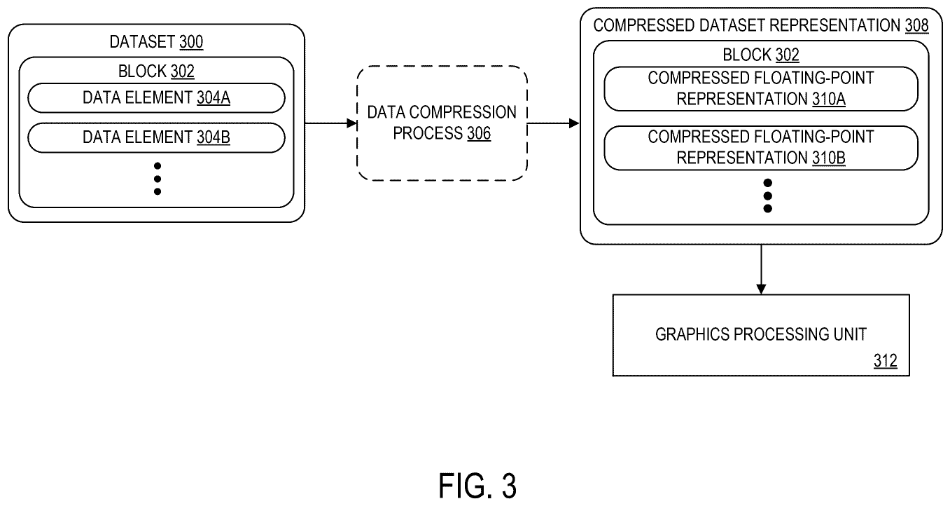

Returning briefly to FIG. 2, at 204, method 200 includes calculating compressed floating-point representations for the subset of data elements of each block. This is schematically illustrated with respect to FIG. 3, showing an example dataset 300. The dataset has been divided into a plurality of blocks as discussed above, one of which is labelled as block 302. Block 302 includes at least two data elements 304A and 304B. The dataset is input to a data compression process 306, which outputs a compressed dataset representation 308. The data elements have been converted into compressed floating-point representations 310A and 310B corresponding to the data elements. After compression, block 302 of compressed dataset representation 308 is stored using fewer bits of data as compared to dataset 300. This is due at least in part to the sharing of exponents between different compressed floating-point representations, as will be described in more detail below. The compressed dataset representation 308 is transmitted to a graphics processing unit (GPU) 312 for processing. As discussed above, the compressed dataset representation is represented using a smaller quantity of bits as compared to the original dataset prior to compression. As such, the transmission of the compressed representation of the dataset uses less memory bandwidth of the GPU as compared to transmission of the dataset of data elements, which beneficially improves the performance of the GPU and the overall computing system.

Returning briefly to FIG. 2, the data compression process includes, at 206 of method 200, selecting a selected exponent from a shared set of two or more exponents for each data element. In other words, rather than calculating a separate unique exponent for each data element, exponents are selected from a predetermined list, and two or more data elements in the block share the same selected exponent. This beneficially reduces the storage space required to store the compressed representation of the dataset—e.g., storage space is conserved by not storing separate unique exponents for each data element.

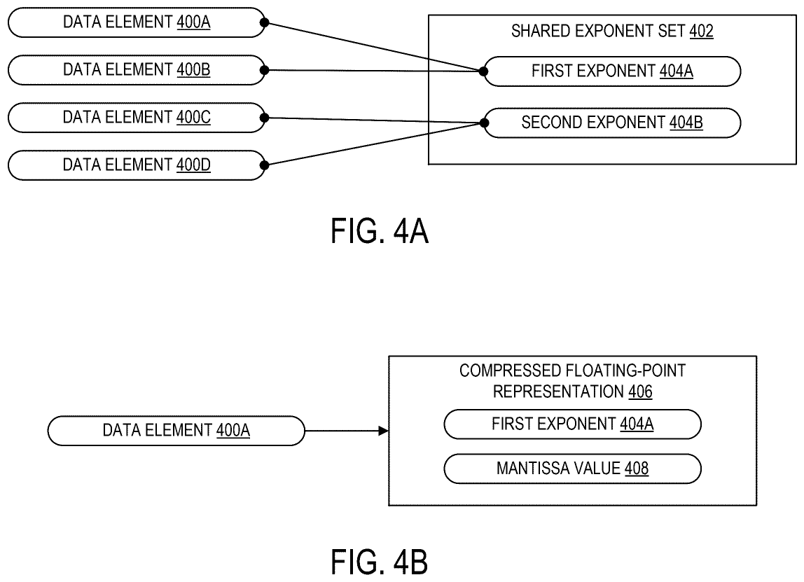

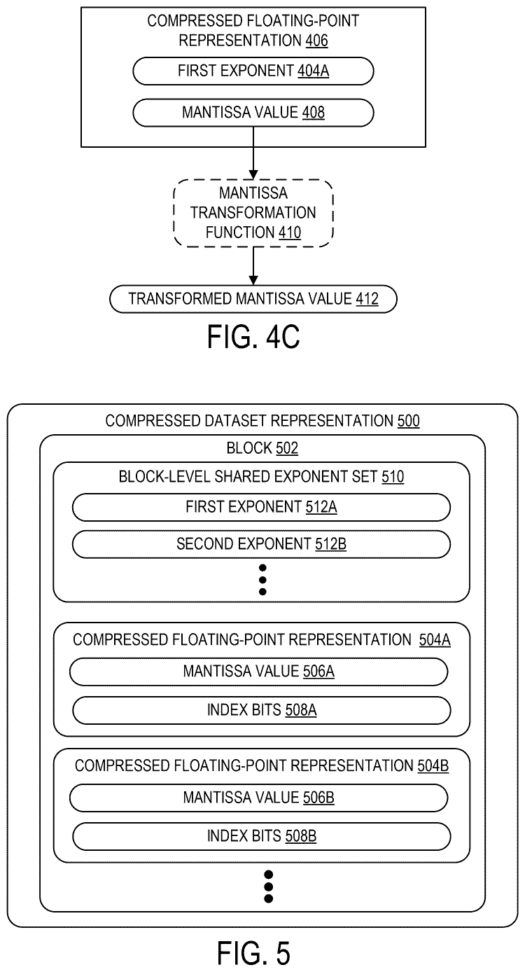

This is schematically illustrated with respect to FIG. 4A, showing a plurality of data elements 400A and 400B, which are included in a larger dataset to be compressed. Each of the data elements 400A-400D are included in the same block—e.g., similar to data elements 304A and 304B of FIG. 3. FIG. 4A additionally shows a shared exponent set 402, including a first exponent 404A and a second exponent 404B, to be shared between the data elements of the block. As shown, the system has selected first exponent 404A for data elements 400A and 400B, and has selected second exponent 404B for data elements 400C and 400D. In some cases, the exponents 404A and 404B are selected from a larger predetermined set of exponent pairs. In other words, exponents 404A and 404B may be one pair of exponents from a set of exponent pairs that are either predefined prior to the compression process (e.g., a static list of exponent pairs), or are calculated based on the values of the data elements in the dataset.

Exponents are selected for each data element based on the relative values of each data element. For instance, different data elements in each block may differ by several orders of magnitude. This is the case in the dark frame calibration image of FIG. 1A, where pixel values can range from relatively low values to relatively high values within the same block. As such, one exponent from the exponent set may be selected for data elements in a block having relatively low values, while another exponent is selected for data elements having higher values—e.g., orders of magnitude higher. In one example approach, the system may select an exponent pair from a shared set of exponents, where the higher exponent of the pair is selected based on the highest initial exponent present among the data elements of the block being compressed. For any data elements having initial exponents that are lower than or equal to the lower exponent of the selected exponent pair, the lower exponent is used. Otherwise, for data elements having initial exponents that are higher than the lower exponent of the selected exponent pair, the higher exponent of the selected pair is used.

In some examples, use of shared exponents in this manner can enable more efficient encoding of negative data element values. For instance, one or more exponents in the shared exponent set may be used to represent data elements having negative values. This can alleviate the need to store a sign bit for each compressed floating-point representation. Rather, the signs of the compressed floating-point representations may be distinguished by which of the shared exponents they use. For instance, all positive-value data elements in a block may use one exponent, while all negative-value data elements in the block use another. This can beneficially conserve storage space over cases where explicit sign bits are used.

Additionally, or alternatively, explicit sign bits may still be used in some cases. For instance, explicit sign bits may serve better when the distribution of negative and positive bits is symmetric around zero. However, use of dedicated exponents in the shared exponent set for negative values may serve better when the negative values are relatively smaller than the positive values. In some cases, both explicit sign bits and dedicated negative exponents may be used for the same dataset—e.g., this may differ between different blocks. In some examples, one exponent value can be reserved for special cases—e.g., not-a-number (NaN) and infinite (Inf).

The shared set of exponents may be determined in any suitable way. In some examples, the shared set of exponents may be a predetermined set useable to approximate a broad range of different data elements—e.g., differing by several orders of magnitude. For instance, a fixed set of exponent pairs could include {[0,3] [1,4] [2,6] [3,8]}, as one non-limiting example.

Alternatively, in some examples, the shared set of exponents may be pre-calculated based on the values of the data elements in a given block, and/or based on the values of the data elements of the overall dataset. One non-limiting example approach will now be described, in which the shared set of exponents is determined based on the values of the data elements in the overall dataset.

In this example approach, the system first identifies all of the unique exponents in the dataset. Next, the system generates a first list of size N, where N is equal to the number of unique exponents in the dataset. The first list is populated with each of the N unique exponents. The system then generates histograms for each of the N exponents in the list. Next, for each block of the dataset, the system identifies the highest exponent of the data elements in the block, and selects the histogram corresponding to that same exponent in the first list. The system populates the selected histogram with the other exponents of the data elements in the block.

Next, the system generates a second list of size N. For each of the N histograms, the system selects one exponent in the histogram that minimizes either the maximum distance or the average distance to each of the other exponents present in the histogram. This may in some cases be done using brute force search, since the number of exponents in each histogram is relatively low. The selected exponents from each histogram are inserted into the second list. The first and second lists are then merged to form the shared set of exponents, including N total exponent pairs. At this point, exponent pairs may be selected from the shared set of exponents when compressing blocks of the dataset. For instance, as discussed above, the first exponent 404A and second exponent 404B may be a pair of exponents identified in this manner, and selected for data elements 400A-400D from among a set of other exponent pairs.

In the example discussed above, the shared set of exponents includes N exponent pairs, and exponent pairs are selected for each block in the dataset. In other examples, however, more exponents may be selected for each block. For instance, three or more exponents may be selected for each block—e.g., in cases where there is significant variety in the data elements of the block. Furthermore, in the approach described above, each exponent pair includes a different unique first exponent. However, in some examples, additional exponent pair combinations could be allocated to improve compression efficiency. For instance, additional pairs, where the first exponent is a duplicate of another first exponent and the second exponent is any exponent other than the corresponding second exponent of the another first exponent, could be added until the list size reaches a power of two value.

The present disclosure primarily describes the selected exponents as being stored in each block. This may be referred to as a block-level exponent set, where each block in the dataset includes its own respective set of exponents. However, as will be described in more detail below, the exponents may in some cases be stored in a dataset-level exponent set, and each block includes index values relative to the dataset-level exponent set. For instance, data elements of a block may be associated with index bits relative to a block-level index, and the block-level index in turn specifies which exponents were selected from a larger dataset-level exponent set.

Returning briefly to FIG. 2, at 208, the data compression process includes calculating a mantissa value for each data element in the block, such that the mantissa value and the selected exponent for the data element together comprise a compressed floating-point representation of the data element. This is schematically illustrated with respect to FIG. 4B, in which a compressed floating-point representation 406 is determined for data element 400A. As shown, the compressed floating-point representation includes the first exponent 404A selected for data element 400A, and a mantissa value 408 calculated for the data element.

The mantissa may be calculated in any suitable way, depending on the value of the selected exponent and the value of the initial data element. For instance:

Mantissaᵥₐₗᵤₑ=ldexp(initial dataᵥₐₗᵤₑ,−exponent)

In some cases, the calculated mantissa values may each range between zero and one, as compared to other approaches, where mantissa values typically range between one and two. This is because different data elements in the same block may share the same exponent, meaning the precision of the floating-point representations would be reduced when mantissa values between one and two are used. In other words, in some cases, the precision of the compressed floating-point representations generated as described herein may be improved by using mantissa values that range between zero and one.

In some cases, the minimum mantissa value for certain exponents may be greater than zero. For instance, because multiple exponents are stored per block, the range of possible values that can be encoded using these exponents would overlap with each other. As such, precision for higher exponents can beneficially be improved by removing overlapping exponent coverage between the multiple exponents during encoding. One approach to removing the overlapping regions includes calculating a minimum mantissa value for each exponent, where the minimum value for a specific exponent is the maximum value that can be encoded by the next smaller exponent. For instance, if a pair of selected exponents includes four and six, then the smaller exponent (e.g., four) would be used to encode values between [0, 16], and the higher exponent (e.g., six) would be used to encode values between [16, 64]. In other words, in this approach, a pair of exponents is selected, including a first exponent and a second exponent higher than the first exponent. A minimum mantissa value for the second exponent is then set to a positive non-zero mantissa value determined based at least in part on the first exponent—e.g., to avoid covering an overlapping range with the first exponent.

In some examples, prior to storing a calculated mantissa value as part of a compressed floating-point representation, the mantissa value is first transformed using a mantissa transformation function. This is schematically illustrated with respect to FIG. 4C, again showing compressed floating-point representation 406 of FIG. 4B, which includes the first selected exponent 404A and the mantissa value 408. As shown, the mantissa value is input into a mantissa transformation function 410, which transforms the mantissa value into a transformed mantissa value 412. This may beneficially improve the precision with which certain data elements are represented after compression—e.g., data elements close to zero.

As one non-limiting example, the mantissa transformation function may be a square root function, and the decoding transformation may be a power-of-two function. This may beneficially serve to improve precision for small mantissa values. Furthermore, use of a square-root function may make it possible to store smaller mantissa values than would be possible without a mantissa transformation function. For instance, for an 8-bit mantissa value, the smallest non-zero mantissa that can be encoded without the use of a transformation function is 1/256. By contrast, when a transformation function is used, mantissa values as low as 1/65,536 can be represented. The following table illustrates the improvement in precision for relatively small exponent values, as compared to cases where no transformation is performed.

| Mantissa value | Relative Precision |
|---|---|
| 0.25 | 1x |
| 0.0625 | 2x |
| 0.015625 | 4x |
| 0.00390625 | 8x |

Returning briefly to FIG. 2, at 210, method 200 includes storing the compressed floating-point representations for the subset of data elements of each block in a compressed representation of the dataset. For instance, in FIG. 3, dataset 300 is stored as compressed dataset representation 308. The compressed dataset representation may be stored in any suitable computer storage device—e.g., volatile memory, non-volatile storage, removable storage, etc.

FIG. 5 schematically shows another non-limiting example of a compressed dataset representation 500. As shown, the compressed dataset representation includes a block 502, which is one of a plurality of blocks of the dataset. Block 502 includes at least two compressed floating-point representations 504A and 504B. In this example, the compressed floating-point representations each include mantissa values 506A/506B, which may have been transformed using a mantissa transformation function as discussed above.

However, rather than storing different unique exponents for each mantissa value, in this example the system stores one or more index bits for each mantissa value. The index bits specify which of the shared set of exponents is the selected exponent for that compressed floating-point representation. For instance, compressed floating-point representation 504A includes is associated with index bits 508A, and compressed floating-point representation 504B is associated with index bits 508B. The index bits refer to exponents in a shared exponent set 510. In this example, the shared exponent set is stored in block 502 as a block-level exponent set—e.g., shared between the compressed floating-point representations of a single block. The shared exponent set 510 includes at least a first exponent 512A, and a second exponent 512B. The index bits of each compressed floating-point representation indicate which of these exponents is used for that compressed floating-point representation.

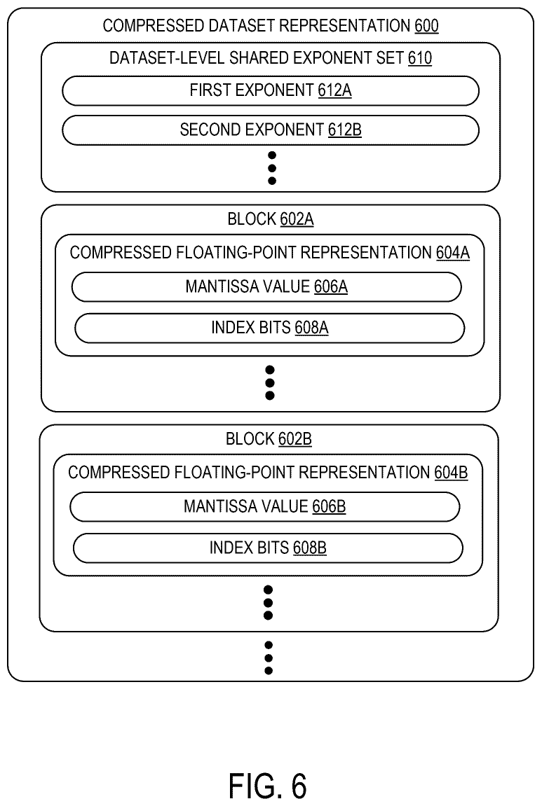

In this example, the shared exponent set is a block-level exponent set, and is therefore only shared between the data elements of a single block. In other examples, however, the shared exponent set may be a dataset-level exponent set, shared between each of the plurality of blocks. This is schematically illustrated with respect to FIG. 6, showing another example compressed dataset representation 600. This includes at least two blocks 602A and 602B, out of a plurality of blocks in the compressed dataset representation. Each block includes a plurality of respective compressed floating-point representations. In this example, one compressed floating-point representation is shown for each block—e.g., block 602A includes representation 604A, and block 602B includes representation 604B. Each compressed-floating point representation has an associated mantissa value 606A/606B, and set of index bits 608A/608B.

However, in this example, the index bits refer to a dataset-level shared exponent set 610, which is shared between each of the plurality of blocks of the dataset. As shown, this includes at least a first exponent 612A and a second exponent 612B. Each of the various compressed floating-point representations in the compressed dataset representation may be associated with different respective index bits, specifying which of the exponents in the exponent set 610 correspond to that data element. As discussed above, this may conserve data storage space as compared to cases where different unique exponents are encoded and stored for each individual data element. Rather, in this case, at least two or more data elements share the same exponent.

In general, however, the various types of data stored herein may be stored in any suitable way, using any suitable encoding system, and using any suitable amount of data for each field. For instance, depending on the block size, different numbers of bits can be used for storing exponents. As examples, 16 bits could be used to store two exponents with 8 bits each, three exponents with 5 bits each, etc. In some examples, the shared set of exponents may be stored using delta encoding, such that a second exponent of the set is defined as an offset relative to a first exponent of the set. This can beneficially contribute to conserving storage space, especially when relatively large exponents are used.

In general, it may be advantageous to store data in multiples of 8, 16, or 32 bits in GPU image processing scenarios. As such, as non-limiting examples, 32, 40, or 48 bits could be used for storing 2×2 blocks of image pixel data. If 4 bits are reserved for storing index values for each data element (e.g., one bit per block element), and 4 bits are used for storing a block-level index (e.g., relative to a dataset-level list of 16 exponent pairs), then 6, 8, or 10 bits could be used for storing mantissa values, for a total size of 32, 40, or 48 bits, respectively.

In another example, 160 bits could be used to store a block size of 4×4. One bit may be reserved for selecting between the two signed modes, 15 bits may be reserved for storing four exponents using delta encoding, 32 bits may be reserved for storing indices (2 bits per block element), and 6 or 7 bits may be used to store the mantissa values depending on whether an explicit sign bit is used or not.

Furthermore, as discussed above, the block sizes discussed herein are non-limiting examples, and much larger block sizes can be used. Furthermore, non-square block sizes can be used, such as 32×4, which may beneficially reduce the overhead of storing exponents. It will be understood that the block size used may vary depending on the implementation—e.g., based on the degree of correlation between data elements in a block, and whether the read/write pattern typically accesses neighboring data elements. Furthermore, the block size and quantity of bits reserved per block may also be dynamically changed based on statistics that are calculated during encoding. This may be beneficial when, for example, multiple frames of data are compressed that each have similar statistics, such as multiple consecutive video frames.

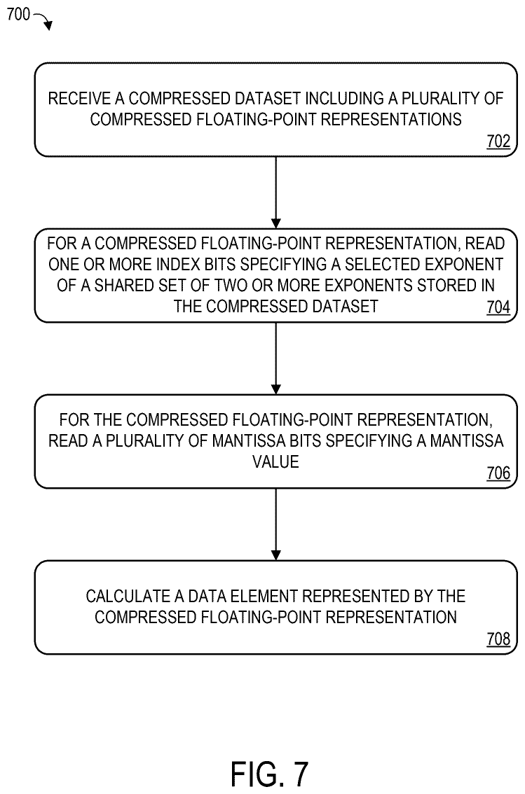

The present disclosure has thus far primarily focused on compressing data into compressed floating-point representations. FIG. 7 illustrates an example method 700 for decompressing data that has been compressed according to the techniques described above. As with method 200, method 700 may be initiated, terminated, and/or repeated at any suitable time and in response to any suitable condition. Steps of method 700 may be implemented by any suitable computing system of one or more computing devices. Any computing device implementing steps of method 700 may have any suitable capabilities, hardware configuration, and form factor. As one example, method 700 may be implemented by computing system 800 described below with respect to FIG. 8.

At 702, method 700 includes receiving a compressed dataset including a plurality of compressed floating-point representations. The compressed floating-point representations are divided into a plurality of blocks each having the same predetermined size. The compressed dataset may be retrieved in any suitable way, from any suitable source. For instance, the compressed dataset may be loaded from computer memory, non-volatile storage, removable storage, and/or accessed over a computer network. The computer network may include local computer networks and/or wide-area computer networks, such as the internet.

At 704, method 700 includes, for a compressed floating-point representation in a block of the plurality of blocks, reading one or more index bits specifying a selected exponent of a set of two or more shared exponents. The set of exponents may be block-level (e.g., shared between data elements of the same block) or dataset-level (e.g., shared between all blocks of the dataset) depending on the implementation. As discussed above, two or more data elements in a given block share the same exponent of the exponent set, which beneficially results in conservation of data storage space.

At 706, method 700 includes, for the compressed floating-point representation, reading a plurality of mantissa bits specifying a mantissa value of the compressed floating-point value. At 708, method 700 includes, based at least in part on the selected exponent referenced by the index bits, and the mantissa value, calculating a data element represented by the compressed floating-point representation. This may be repeated any number of times, for any number of data elements within the data set. For instance, method 700 may be performed for one or more requested blocks including requested data, or for every block of the dataset, depending on the context.

The methods and processes described herein may be tied to a computing system of one or more computing devices. In particular, such methods and processes may be implemented as an executable computer-application program, a network-accessible computing service, an application-programming interface (API), a library, or a combination of the above and/or other compute resources.

FIG. 8 schematically shows a simplified representation of a computing system 800 configured to provide any to all of the compute functionality described herein. Computing system 800 may take the form of one or more personal computers, network-accessible server computers, tablet computers, home-entertainment computers, gaming devices, mobile computing devices, mobile communication devices (e.g., smart phone), virtual/augmented/mixed reality computing devices, wearable computing devices, Internet of Things (IoT) devices, embedded computing devices, and/or other computing devices.

Computing system 800 includes a logic subsystem 802 and a storage subsystem 804. Computing system 800 may optionally include a display subsystem 806, input subsystem 808, communication subsystem 810, and/or other subsystems not shown in FIG. 8.

Logic subsystem 802 includes one or more physical devices configured to execute instructions. For example, the logic subsystem may be configured to execute instructions that are part of one or more applications, services, or other logical constructs. The logic subsystem may include one or more hardware processors configured to execute software instructions. Additionally, or alternatively, the logic subsystem may include one or more hardware or firmware devices configured to execute hardware or firmware instructions. Processors of the logic subsystem may be single-core or multi-core, and the instructions executed thereon may be configured for sequential, parallel, and/or distributed processing. Individual components of the logic subsystem optionally may be distributed among two or more separate devices, which may be remotely located and/or configured for coordinated processing. Aspects of the logic subsystem may be virtualized and executed by remotely-accessible, networked computing devices configured in a cloud-computing configuration.

Storage subsystem 804 includes one or more physical devices configured to temporarily and/or permanently hold computer information such as data and instructions executable by the logic subsystem. When the storage subsystem includes two or more devices, the devices may be collocated and/or remotely located. Storage subsystem 804 may include volatile, nonvolatile, dynamic, static, read/write, read-only, random-access, sequential-access, location-addressable, file-addressable, and/or content-addressable devices. Storage subsystem 804 may include removable and/or built-in devices. When the logic subsystem executes instructions, the state of storage subsystem 804 may be transformed—e.g., to hold different data.

Aspects of logic subsystem 802 and storage subsystem 804 may be integrated together into one or more hardware-logic components. Such hardware-logic components may include program- and application-specific integrated circuits (PASIC/ASICs), program- and application-specific standard products (PSSP/ASSPs), system-on-a-chip (SOC), and complex programmable logic devices (CPLDs), for example.

The logic subsystem and the storage subsystem may cooperate to instantiate one or more logic machines. As used herein, the term “machine” is used to collectively refer to the combination of hardware, firmware, software, instructions, and/or any other components cooperating to provide computer functionality. In other words, “machines” are never abstract ideas and always have a tangible form. A machine may be instantiated by a single computing device, or a machine may include two or more sub-components instantiated by two or more different computing devices. In some implementations a machine includes a local component (e.g., software application executed by a computer processor) cooperating with a remote component (e.g., cloud computing service provided by a network of server computers). The software and/or other instructions that give a particular machine its functionality may optionally be saved as one or more unexecuted modules on one or more suitable storage devices.

When included, display subsystem 806 may be used to present a visual representation of data held by storage subsystem 804. This visual representation may take the form of a graphical user interface (GUI). Display subsystem 806 may include one or more display devices utilizing virtually any type of technology. In some implementations, display subsystem may include one or more virtual-, augmented-, or mixed reality displays.

When included, input subsystem 808 may comprise or interface with one or more input devices. An input device may include a sensor device or a user input device. Examples of user input devices include a keyboard, mouse, touch screen, or game controller. In some embodiments, the input subsystem may comprise or interface with selected natural user input (NUI) componentry. Such componentry may be integrated or peripheral, and the transduction and/or processing of input actions may be handled on- or off-board. Example NUI componentry may include a microphone for speech and/or voice recognition; an infrared, color, stereoscopic, and/or depth camera for machine vision and/or gesture recognition; a head tracker, eye tracker, accelerometer, and/or gyroscope for motion detection and/or intent recognition.

When included, communication subsystem 810 may be configured to communicatively couple computing system 800 with one or more other computing devices. Communication subsystem 810 may include wired and/or wireless communication devices compatible with one or more different communication protocols. The communication subsystem may be configured for communication via personal-, local- and/or wide-area networks.

This disclosure is presented by way of example and with reference to the associated drawing figures. Components, process steps, and other elements that may be substantially the same in one or more of the figures are identified coordinately and are described with minimal repetition. It will be noted, however, that elements identified coordinately may also differ to some degree. It will be further noted that some figures may be schematic and not drawn to scale. The various drawing scales, aspect ratios, and numbers of components shown in the figures may be purposely distorted to make certain features or relationships easier to see.

In an example, a method for data compression comprises: dividing a dataset of data elements into a plurality of blocks, such that each block includes a subset of data elements, and each block has a same predetermined size, wherein the dataset is represented using a first quantity of bits; calculating compressed floating-point representations for the subset of data elements of each block, wherein the compressed floating-point representations are calculated by: for each data element in a block of the plurality of blocks, selecting a selected exponent from a set of two or more exponents, wherein two or more data elements of the block share the selected exponent; and for each data element in the block, calculating a mantissa value, such that the mantissa value and the selected exponent for the data element together comprise a compressed floating-point representation of the data element; and storing the compressed floating-point representations for the subset of data elements of each block in a compressed representation of the dataset, wherein the compressed representation of the dataset is represented using a second quantity of bits, smaller than the first quantity of bits, to conserve storage space and memory bandwidth of a computing system. In this example or any other example, the method further comprises storing one or more index bits for each compressed floating-point representation, the one or more index bits specifying which of the set of two or more exponents is the selected exponent for the compressed floating-point representation. In this example or any other example, the set of two or more exponents is stored in the block as a block-level exponent set, and wherein the one or more index bits specify the selected exponent relative to the block-level exponent set. In this example or any other example, the set of two or more exponents is stored in a dataset-level exponent set shared between each of the plurality of blocks, and wherein the one or more index bits specify the selected exponent relative to the dataset-level exponent set. In this example or any other example, the set of two or more exponents are stored using delta encoding, such that a second exponent of the set is defined as an offset relative to a first exponent of the set. In this example or any other example, the set of two or more exponents includes a first exponent and a second exponent higher than the first exponent, and wherein a minimum mantissa value of the second exponent is set to a positive non-zero mantissa value determined based at least in part on the first exponent. In this example or any other example, an exponent of the set of two or more exponents is used to represent data elements having negative values. In this example or any other example, the set of two or more exponents is predetermined based at least in part on values of the dataset of data elements. In this example or any other example, each mantissa value is between zero and one. In this example or any other example, the method further comprises transforming the mantissa value using a mantissa transformation function prior to storing the compressed floating-point representation. In this example or any other example, the mantissa transformation function is a square root function. In this example or any other example, the dataset is a digital image, and wherein the data elements are pixel values of the digital image. In this example or any other example, the digital image is a dark frame calibration image.

In an example, a computing system comprises: a logic subsystem; and a storage subsystem holding instructions executable by the logic subsystem to: divide a dataset of data elements into a plurality of blocks, such that each block includes a subset of data elements, and each block has a same predetermined size, wherein the dataset is represented using a first quantity of bits; calculate compressed floating point representations for the subset of data elements of each block, wherein the compressed floating-point representations are calculated by: for each data element in a block of the plurality of blocks, selecting a selected exponent from a set of two or more exponents, wherein two or more data elements of the block share the selected exponent; and for each data element in the block, calculating a mantissa value, such that the mantissa value and the selected exponent for the data element together comprise a compressed floating-point representation of the data element; and store the compressed floating-point representations for the subset of data elements of each block in a compressed representation of the dataset, wherein the compressed representation of the dataset is represented using a second quantity of bits, smaller than the first quantity of bits, to conserve storage space and memory bandwidth of a computing system. In this example or any other example, the instructions are further executable to store one or more index bits for each compressed floating-point representation, the one or more index bits specifying which of the set of two or more exponents is the selected exponent for the compressed floating-point representation. In this example or any other example, the set of two or more exponents is stored in the block as a block-level exponent set, and wherein the one or more index bits specify the selected exponent relative to the block-level exponent set. In this example or any other example, the set of two or more exponents is predetermined based at least in part on values of the dataset of data elements. In this example or any other example, each mantissa value is between zero and one. In this example or any other example, the instructions are further executable to transform the mantissa value using a square root transformation function prior to storing the compressed floating-point representation.

In an example, a method for data compression to conserve memory bandwidth of a graphics processing unit (GPU) comprises: receiving a dataset of data elements to be processed by the GPU, the dataset of data elements represented using a first quantity of bits; dividing a dataset of data elements into a plurality of blocks, such that each block includes a subset of data elements, and each block has a same predetermined size; calculating compressed floating-point representations for the subset of data elements of each block, wherein the compressed floating-point representations are calculated by: for each data element in a block of the plurality of blocks, selecting a selected exponent from a set of two or more exponents, wherein two or more data elements of the block share the selected exponent; and for each data element in the block, calculating a mantissa value, such that the mantissa value and the selected exponent for the data element together comprise a compressed floating-point representation of the data element; storing the compressed floating-point representations for the subset of data elements of each block in a compressed representation of the dataset, wherein the compressed representation of the dataset is represented using a second quantity of bits, lower than the first quantity of bits; and transmitting the compressed representation of the dataset to the GPU for processing, such that transmission of the compressed representation of the dataset uses less memory bandwidth of the GPU as compared to transmission of the dataset of data elements.

It will be understood that the configurations and/or approaches described herein are exemplary in nature, and that these specific embodiments or examples are not to be considered in a limiting sense, because numerous variations are possible. The specific routines or methods described herein may represent one or more of any number of processing strategies. As such, various acts illustrated and/or described may be performed in the sequence illustrated and/or described, in other sequences, in parallel, or omitted. Likewise, the order of the above-described processes may be changed.

The subject matter of the present disclosure includes all novel and non-obvious combinations and sub-combinations of the various processes, systems and configurations, and other features, functions, acts, and/or properties disclosed herein, as well as any and all equivalents thereof.

1. A method for data compression, the method comprising:
dividing a dataset of data elements into a plurality of blocks, such that each block includes a subset of data elements, and each block has a same predetermined size, wherein the dataset is represented using a first quantity of bits;
calculating compressed floating-point representations for the subset of data elements of each block, wherein the compressed floating-point representations are calculated by:
for each data element in a block of the plurality of blocks, selecting a selected exponent from a set of two or more exponents, wherein two or more data elements of the block share the selected exponent; and
for each data element in the block, calculating a mantissa value, such that the mantissa value and the selected exponent for the data element together comprise a compressed floating-point representation of the data element; and
storing the compressed floating-point representations for the subset of data elements of each block in a compressed representation of the dataset, wherein the compressed representation of the dataset is represented using a second quantity of bits, smaller than the first quantity of bits, to conserve storage space and memory bandwidth of a computing system.

2. The method of claim 1, further comprising storing one or more index bits for each compressed floating-point representation, the one or more index bits specifying which of the set of two or more exponents is the selected exponent for the compressed floating-point representation.

3. The method of claim 2, wherein the set of two or more exponents is stored in the block as a block-level exponent set, and wherein the one or more index bits specify the selected exponent relative to the block-level exponent set.

4. The method of claim 2, wherein the set of two or more exponents is stored in a dataset-level exponent set shared between each of the plurality of blocks, and wherein the one or more index bits specify the selected exponent relative to the dataset-level exponent set.

5. The method of claim 1, wherein the set of two or more exponents are stored using delta encoding, such that a second exponent of the set is defined as an offset relative to a first exponent of the set.

6. The method of claim 1, wherein the set of two or more exponents includes a first exponent and a second exponent higher than the first exponent, and wherein a minimum mantissa value of the second exponent is set to a positive non-zero mantissa value determined based at least in part on the first exponent.

7. The method of claim 1, wherein an exponent of the set of two or more exponents is used to represent data elements having negative values.

8. The method of claim 1, wherein the set of two or more exponents is predetermined based at least in part on values of the dataset of data elements.

9. The method of claim 1, wherein each mantissa value is between zero and one.

10. The method of claim 1, further comprising transforming the mantissa value using a mantissa transformation function prior to storing the compressed floating-point representation.

11. The method of claim 10, wherein the mantissa transformation function is a square root function.

12. The method of claim 1, wherein the dataset is a digital image, and wherein the data elements are pixel values of the digital image.

13. The method of claim 12, wherein the digital image is a dark frame calibration image.

14. A computing system, comprising:
a logic subsystem; and
a storage subsystem holding instructions executable by the logic subsystem to:
divide a dataset of data elements into a plurality of blocks, such that each block includes a subset of data elements, and each block has a same predetermined size, wherein the dataset is represented using a first quantity of bits;
calculate compressed floating point representations for the subset of data elements of each block, wherein the compressed floating-point representations are calculated by:
for each data element in a block of the plurality of blocks, selecting a selected exponent from a set of two or more exponents, wherein two or more data elements of the block share the selected exponent; and
for each data element in the block, calculating a mantissa value, such that the mantissa value and the selected exponent for the data element together comprise a compressed floating-point representation of the data element; and
store the compressed floating-point representations for the subset of data elements of each block in a compressed representation of the dataset, wherein the compressed representation of the dataset is represented using a second quantity of bits, smaller than the first quantity of bits, to conserve storage space and memory bandwidth of a computing system.

15. The computing system of claim 14, wherein the instructions are further executable to store one or more index bits for each compressed floating-point representation, the one or more index bits specifying which of the set of two or more exponents is the selected exponent for the compressed floating-point representation.

16. The computing system of claim 15, wherein the set of two or more exponents is stored in the block as a block-level exponent set, and wherein the one or more index bits specify the selected exponent relative to the block-level exponent set.

17. The computing system of claim 14, wherein the set of two or more exponents is predetermined based at least in part on values of the dataset of data elements.

18. The computing system of claim 14, wherein each mantissa value is between zero and one.

19. The computing system of claim 14, further comprising transforming the mantissa value using a square root transformation function prior to storing the compressed floating-point representation.

20. A method for data compression to conserve memory bandwidth of a graphics processing unit (GPU), the method comprising:
receiving a dataset of data elements to be processed by the GPU, the dataset of data elements represented using a first quantity of bits;
dividing a dataset of data elements into a plurality of blocks, such that each block includes a subset of data elements, and each block has a same predetermined size;
calculating compressed floating-point representations for the subset of data elements of each block, wherein the compressed floating-point representations are calculated by:
for each data element in a block of the plurality of blocks, selecting a selected exponent from a set of two or more exponents, wherein two or more data elements of the block share the selected exponent; and
for each data element in the block, calculating a mantissa value, such that the mantissa value and the selected exponent for the data element together comprise a compressed floating-point representation of the data element;
storing the compressed floating-point representations for the subset of data elements of each block in a compressed representation of the dataset, wherein the compressed representation of the dataset is represented using a second quantity of bits, lower than the first quantity of bits; and
transmitting the compressed representation of the dataset to the GPU for processing, such that transmission of the compressed representation of the dataset uses less memory bandwidth of the GPU as compared to transmission of the dataset of data elements.
